(19) United States
(12) Patent Application Publication
(10) Pub. No.: US 2007/0115157 A1
(43) Pub. Date: May 24, 2007

(54) Method and system for generation of double-sided pulse wave modulation signal

(76) Inventor: Zhuan Ye, Vernon Hills, IL (US)

Correspondence Address: MOTOROLA, INC., 1303 EAST ALGONQUIN ROAD, IL01/3RD, SCHAUMBURG, IL, 60196, US

(21) Appl. No.: 11/284,529

(22) Filed: Nov. 21, 2005

(51) Int. Cl. H03M 3/00

(52) U.S. Cl. 341/143

(57) ABSTRACT

A method and system for generating a double-sided pulse width modulation (PWM) signal (110) is disclosed. The method includes generating a leading edge PWM signal and a trailing edge PWM signal from a pulse code modulation (PCM) data stream (102) using a modulation conversion circuitry (106). The method further includes combining the leading edge PWM signal and the trailing edge PWM signal to form a double-sided PWM signal using a combining circuitry (108).

### FIELD OF THE INVENTION

The present invention generally relates to the field of integrated circuits, and more specifically to, generation of pulse width modulation (PWM) signals.

### BACKGROUND OF THE INVENTION

Pulse width modulation (PWM) signals are increasingly being used in various applications of switching amplifiers. Most high efficiency switching amplifiers are based on the principle of PWM, which is used in a variety of applications, including digital audio amplifiers and control applications including motor controllers. Typically, a pulse code modulation (PCM) data stream is converted to a PWM signal to achieve high efficiency and accuracy. A double-sided PWM signal is a pulse width modulated signal that has both its leading edge and trailing edge modulated by an information source.

Several methods are known in the art for generating a PWM signal from a PCM data stream. Implementation of these methods for generation of the double-sided PWM signal generally require the signal processing operations to be running at a frequency that is twice of a switching frequency of the PWM signal. In order to accommodate the bandwidth requirements of common modulated RF signals, the switching frequencies of the PWM signal are generally chosen to be above 100 MHz. Therefore, the signal processing operations involved for generation of PWM signals require a sample frequency above 200 MHz. It is very difficult to realize the algorithms used in generation of double-sided PWM signal using moderate technology with such a high sample frequency requirement. In order to generate digital pulse signals at radio frequency, the PWM signals are first generated at baseband before being modulated to radio frequency using digital clock signals. The clock signals normally consist of one in-phase (I) clock and one quardrature (Q) clock. The phases of these clocks differ from each other by 90 degrees. Therefore, if single sided PWM signals are formed at the baseband, their transition edges cannot be aligned with both clock signals. The mis-alignment generates extra transition edges when modulating the baseband PWM signals to radio frequency, multiplying the digital clock signals with the baseband PWM signals. These extra transition edges will cause distortions to the signals at radio frequency. Double sided PWM signals can avoid the occurrence of such distortion by aligning baseband in-phase (I) PWM signal and quardrature (Q) PWM signal with their corresponding clock signals.

In one of the known methods for generation of double sided PWM signals, first an in-phase and a quadrature phase components of a PWM signal are generated in baseband. Then, a pair of clock signals is generated with a desired carrier frequency to modulate the baseband PWM signals to radio frequency digital pulse signals. The signal processing operations in this method are executed at twice the switching frequency of the PWM signals. As described earlier, a high sample frequency requirement makes it very difficult to implement a real time PWM system with radio frequency output.

### BRIEF DESCRIPTION OF FIGURES

The present invention is illustrated by way of example and not limitation in the accompanying figures, in which like references indicate similar elements, and in which:

FIG. 1 representatively illustrates a block diagram of a system for generating a double-sided PWM signal, in accordance with various embodiments of the present invention.

FIG. 2 representatively illustrates a schematic block diagram of a circuitry for generating a double-sided pulse width modulation (PWM) signal, in accordance with an embodiment of the present invention.

FIG. 3 represents a flowchart depicting a method for generating a double-sided PWM signal, in accordance with various embodiments of the present invention.

FIG. 4 represents a flowchart depicting a method for generating a double-sided PWM signal, in accordance with another embodiment of the present invention.

FIG. 5 illustrates a spectrum analyzer screenshot that displays an output of the circuitry for generating a double-sided PWM signal.

### DETAILED DESCRIPTION OF FIGURES

Before describing in detail the particular method and system for generation of double-sided pulse width modulation signal in accordance with various embodiments of the present invention, it should be observed that the present invention resides primarily in combinations of method steps and apparatus components related to generation of double-sided pulse width modulation signal. Accordingly, the apparatus components and method steps have been represented where appropriate by conventional symbols in the drawings, showing only those specific details that are pertinent to understanding the present invention so as not to obscure the disclosure with details that will be readily.

In this document, relational terms such as first and second, and the like may be used solely to distinguish one entity or action from another entity or action without necessarily requiring or implying any actual such relationship or order between such entities or actions. The terms ‘comprises’, ‘comprising’, or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by ‘comprises . . . a’ does not, without more constraints, preclude the existence of additional identical elements in the process, method, article, or apparatus that comprises the element.

A ‘set’ as used in this document, means a non-empty set (i.e., comprising at least one member). The term ‘another’, as used herein, is defined as at least a second or more. The term ‘including’ as used herein, is defined as comprising.

Various embodiments of the present invention provide a method for generating a double-sided pulse width modulation (PWM) signal. The method includes generating a leading edge PWM signal and a trailing edge PWM signal from a pulse code modulation (PCM) data stream. The method further includes combining the leading edge PWM signal and the trailing edge PWM signal for generating the double-sided PWM signal.

Various embodiments of the present invention also provide a system for generating a double-sided PWM signal. The system includes at least one modulation conversion circuitry for generating a leading edge PWM signal and a trailing edge PWM signal from a PCM data stream. The system further includes a combining circuitry capable of combining the leading edge PWM signal and the trailing edge PWM signal to form the double-sided PWM signal.

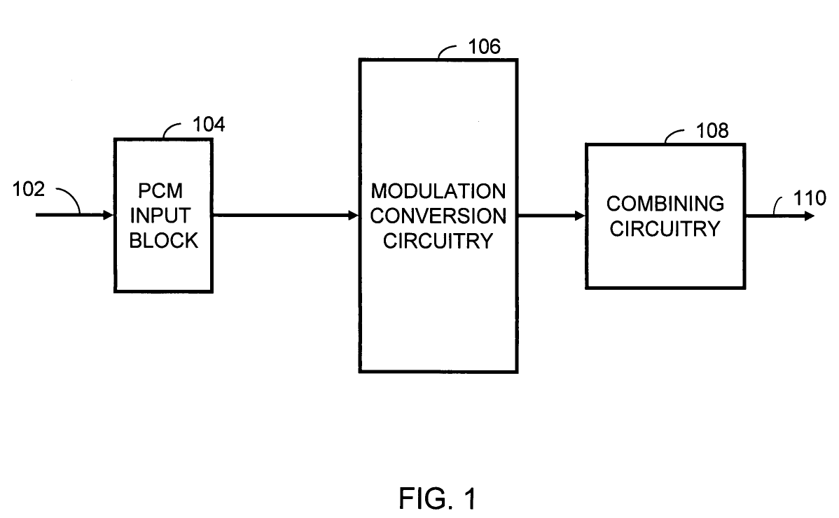

FIG. 1 representatively illustrates a block diagram of a system for generating a double-sided PWM signal, in accordance with various embodiments of the present invention. The system takes a pulse code modulation (PCM) data stream 102 as an input and delivers a double-sided pulse width modulation (PWM) signal 110 as an output of the circuitry. FIG. 1 includes a PCM input block 104, a modulation conversion circuitry 106 and a combining circuitry 108. The PCM data stream 102 can be a received audio signal, a received television audio signal, an Internet audio signal, or any other type of input signal. These input signals may be digital signals and converting them to radio frequency (RF) PWM signals is helpful for processing these input signals. In an embodiment of the present invention, the circuitry of FIG. 1 can be implemented in an integrated circuit. The PCM data stream 102 is input to the PCM input block 104 of the circuitry for generation of double-sided PWM signals. The output of the PCM input block 104 acts as an input to the modulation conversion circuitry 106. The modulation circuitry 106 is capable of generating a leading edge PWM signal and a trailing edge PWM signal from the PCM data stream 102. The output of the modulation conversion circuitry 106 is provided to the combining circuitry 108. The combining circuitry 108 combines the leading edge PWM signal and the trailing edge PWM signal to form a double-sided PWM signal 110. Therefore, the double-sided PWM signal 110 can be viewed as the combination of two single-sided PWM waveforms, one single-sided PWM waveform with its leading edge being modulated and the other single-sided PWM waveform with its trailing edge being modulated. In an embodiment of the present invention, the double-sided PWM signal 110 can be input to a mixer or an output stage of the switching amplifier.

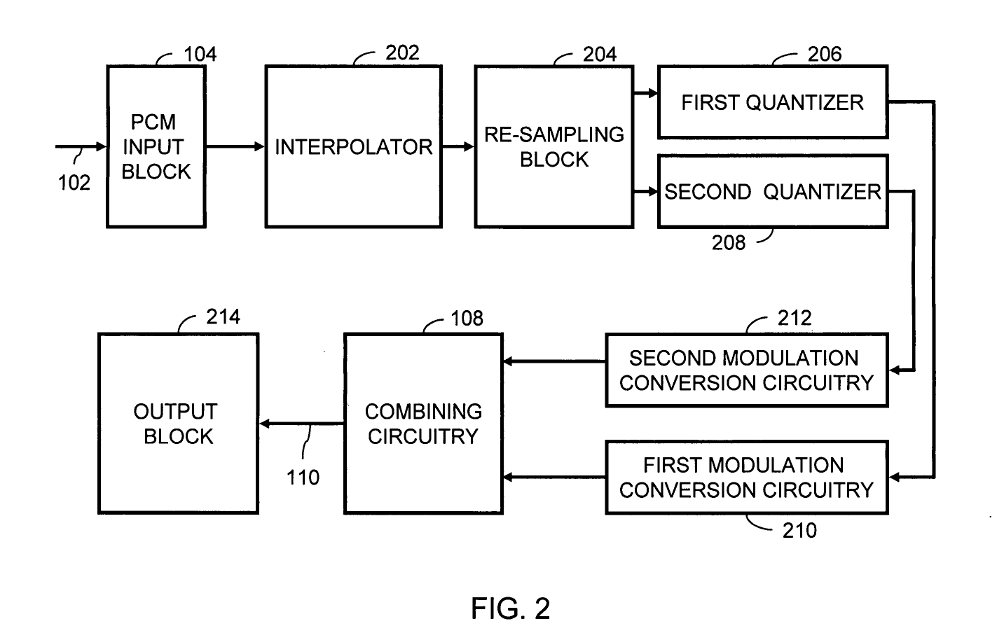

FIG. 2 representatively illustrates a schematic block diagram of a circuitry for generating a double-sided pulse width modulation (PWM) signal, in accordance with an embodiment of the present invention. FIG. 2 shows a PCM input block 102, an interpolator 202, a re-sampling block 204, a first quantizer 206, a second quantizer 208, a first modulation conversion circuitry 210, a second modulation conversion circuitry 212, a combining circuitry 108 and an output block 214. The PCM data stream 102 is input to the PCM input block 104 of the circuitry for generation of the double-sided PWM signal 110. The PCM input block 104 provides the PCM data stream 102 to the interpolator 202. The interpolator 202 is used for changing the sampling rate of the PCM data stream 102 by an integer factor L. The interpolator 202 also increases the sampling rate in order to prepare the PCM data stream 102 to sampling frequency suitable for PWM generation. An exemplary sampling frequency suitable for PWM generation can be taken to be 40 MHz. The re-sampling block 204 re-samples the up-sampled PCM data stream. Further, the re-sampling block 204 creates a first and a second PCM data stream from the up-sampled PCM data stream. The first and the second PCM data streams are non-overlapping in that data elements from the up-sampled PCM data stream will exist on only the first or the second PCM data streams. Re-ampling block 204 creates the first and the second PCM data streams by extracting an odd numbered PCM data stream and an even numbered PCM data stream from the PCM data stream 102. In other words, if the PCM data stream is denoted by {Xₙ}, where n is any integer, the odd numbered PCM data stream includes data from {X₂ₖ₋₁} and the even numbered PCM data stream includes data from {X₂ₖ}, where k is any integer. In an embodiment of the present invention, the sampling frequency of the odd numbered PCM data stream and the sampling frequency of the even numbered PCM data stream are equal to half of the sampling frequency of the PCM data stream 102. The first quantizer 206 quantizes the odd numbered PCM data stream that is output by the re-sampling block 204. Similarly, the second quantizer 208 quantizes the even numbered PCM data stream that is output by the re-sampling block 204. The odd numbered PCM data stream from the first quantizer 206 is provided as an input to the first modulation conversion circuitry 210. The first modulation conversion circuitry 210 converts the odd numbered, PCM data stream to a leading edge PWM signal. The even numbered PCM data stream from the second quantizer 208 is provided as an input to the second modulation conversion circuitry 212. The second modulation conversion circuitry 212 converts the even numbered PCM data stream to a trailing edge PWM signal. It should be appreciated that the roles of the odd numbered PCM data stream and the even numbered PCM data stream are interchangeable. Therefore, the odd numbered PCM data stream can be provided to the second modulation conversion circuitry 212 and be converted to the trailing edge PWM signal. Similarly, the even numbered PCM data stream can be provided to the first modulation conversion circuitry 210 and be converted to the leading edge PWM signal. The leading edge PWM signal and the trailing edge PWM signal are then provided to the combining circuitry 108 that combines them to form the double-sided PWM signal 110. The double-sided PWM signal 110 is a pulse width modulated signal that has both its leading edge and trailing edge modulated by an information source. The output of the combining circuitry 108 can be fed to the output block of a switching amplifier. In an embodiment of the present invention, the output block 214 of the circuitry can be a mixer of a switching amplifier system.

In an alternate embodiment of the invention, a PCM memory can store at least one of the odd numbered PCM data stream and the even numbered PCM data stream that are output by the re-sampling block 204. The odd numbered PCM data stream and the even numbered PCM data stream can then be converted to the leading edge PWM signal and the trailing edge PWM signal (or vice versa) by retrieving the odd numbered PCM data stream or the even numbered PCM data stream from the PCM memory. The PCM memory can be implemented, for example, in the form of a Random Access Memory (RAM). In this embodiment, the leading edge PWM signal and the trailing edge PWM signal can be generated by a single modulation conversion circuitry. A PWM memory can store at least one of the trailing edge PWM signal and the leading edge PWM signal. A single combining circuitry can then combine the leading edge PWM signal and the trailing edge PWM signal to form the double-sided PWM signal 110. In an embodiment of the present invention, the leading edge PWM signal or the trailing edge PWM signal can be retrieved from the PWM memory and can then be combined to form the double-sided PWM signal 110. The PWM memory can be implemented, for example, in the form of a Random Access Memory (RAM).

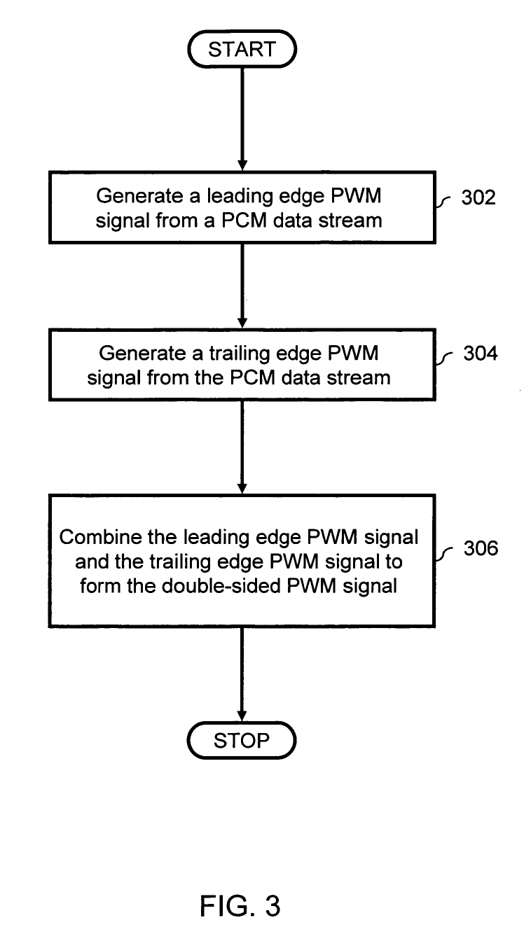

FIG. 3 represents a flowchart depicting a method for generating a double-sided PWM signal, in accordance with various embodiments of the present invention. At step 302, a leading edge PWM signal is generated from the PCM data stream 102. A PCM data stream is received at the PCM input block 104 of the circuitry for generation of the double-sided PWM signal. The modulation conversion circuitry 106 as described in FIG. 1 can be used to convert the PCM data stream to a leading edge PWM signal. At step 304, a trailing edge PWM signal is generated from the PCM data stream. In an embodiment of the invention, both steps 302 and 304 are performed in parallel. The modulation conversion circuitry 106 as described in FIG. 1 can be used to convert the PCM data stream to the trailing edge PWM signal. In an embodiment of the present invention, the switching frequency of the leading edge PWM signal is equal to half of the sampling frequency of the PCM data stream 102. In another embodiment of the present invention, the switching frequency of the trailing edge PWM signal is also equal to half of the sampling frequency of the PCM data stream 102. At step 306, the leading edge PWM signal and the trailing edge PWM signal are combined to form the double-sided PWM signal. The double-sided PWM signal is a pulse width modulated signal that has both its leading edge and trailing edge modulated by the information source.

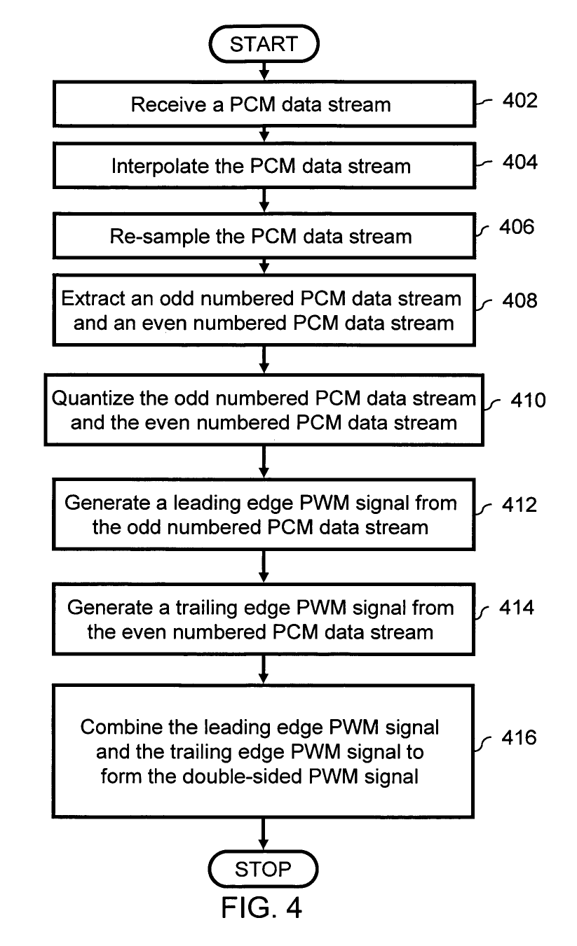

FIG. 4 represents a flowchart depicting a method for generating a double-sided PWM signal, in accordance with another embodiment of the present invention. At step 402, a PCM stream is received at the circuitry for generation of a double-sided PWM signals. The PCM data stream can be received at the PCM input block 104 of the circuitry, as described in FIG. 2. At step 404, the PCM data stream is interpolated for up-sampling the PCM data stream. The interpolator 202, as described earlier in FIG. 2 can be used to interpolate the PCM data stream 102. At step 406, the PCM data stream is re-sampled. The re-sampling block 204 can re-sample the PCM data stream. The sampling rate of the re-sampling block 204 is twice as a switching frequency of the PWM data stream. At step 408, an even numbered PCM data stream and an odd numbered PCM data stream are extracted from the PCM data stream. The re-sampling block 204 can extract the odd numbered PCM data stream and the even numbered PCM data stream from the PCM data stream. At step 410, the odd numbered PCM data stream and the even numbered PCM data stream are quantized. The first quantizer 206 can quantize the PCM data stream used to modulate a leading edge of a PWM signal and the second quantizer 208 can quantize the PCM data stream used to modulate a trailing edge of a PWM signal. At step 412, a leading edge PWM signal is generated from the odd numbered PCM data stream. The first modulation conversion circuitry 210 can generate the leading edge PWM signal from the odd numbered PCM data stream. At step 414, a trailing edge PWM signal is generated from the even numbered PCM data stream. The second modulation conversion circuitry 212 can generate the trailing edge PWM signal from the even numbered PCM data stream. It should be appreciated that the roles of the odd numbered PCM data stream and the even numbered data stream can be exchanged in steps 412 and 414. This means that the leading edge PWM signal can be generated from the even numbered PCM data stream, while the trailing edge PWM signal can be generated from the odd numbered PCM data stream. At step 416, the leading edge PWM signal and the trailing edge PWM signal are combined to form the double-sided PWM signal. The double-sided PWM signal is a pulse width modulated signal that has both its leading edge and trailing edge modulated by the information source.

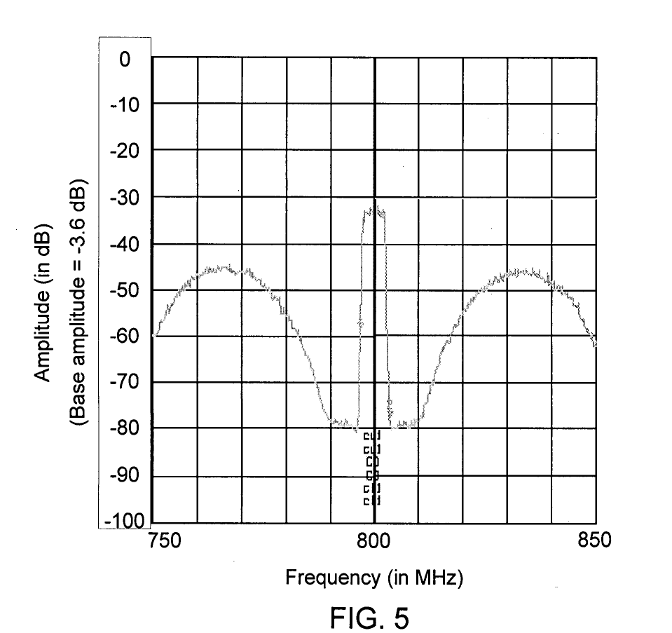

FIG. 5 illustrates a spectrum analyzer graph that displays an exemplary output of the system for generating a double-sided PWM signal, in accordance with various embodiments of the present invention. The spectrum analyzer graph plots magnitude spectra of a double-sided PWM signal with respect to frequency. The spectrum analyzer graph shown in FIG. 5 corresponds to a double-sided PWM signal for which the carrier frequency is 800 MHz and the switching frequency is 100 MHz. Further, the bandwidth of the bandpass signal is 20 MHz.

Various embodiments of the present invention, as described above, generate a double-sided pulse width modulated (PWM) signal. The method and system, as described above, generate the double sided PWM signal at a switching frequency that is half of a sampling frequency of the input PCM data stream. The system for generating a double-sided pulse width modulated (PWM) signal, as described above, reduces power consumption and complexity of an amplifier system.

It will be appreciated the method and system for generation of double-sided pulse width modulation signal in accordance with the present invention described herein may comprise one or more conventional processors and unique stored program instructions that control the one or more processors to implement, in conjunction with certain non-processor circuits, some, most, or all of the functions of the method for generation of double-sided pulse width modulation signal described herein. The non-processor circuits may include, but are not limited to, a radio receiver, a radio transmitter, signal drivers, clock circuits, power source circuits, and user input devices. As such, these functions may be interpreted as steps of a method for generation of double-sided pulse width modulation signal. Alternatively, some or all functions could be implemented by a state machine that has no stored program instructions, or in one or more application specific integrated circuits ASICs, in which each function or some combinations of certain functions are implemented as custom logic. Of course, a combination of the two approaches could be used. Thus, methods and means for these functions have been described herein.

It is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

In the foregoing specification, the invention and its benefits and advantages have been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method for generating a double-sided Pulse Width Modulation (PWM) signal from a pulse code modulated (PCM) data stream, the method comprising:
dividing the PCM data stream into a first and a second non-overlapping PCM data stream;
generating a leading edge pulse width modulated (PWM) signal from the first PCM data stream;
generating a trailing edge pulse width modulated (PWM) signal from the second PCM data stream; and
combining the leading edge PWM signal and the trailing edge PWM signal to form the double-sided PWM signal.

2. The method of claim 1 further comprising a prior step of interpolating the PCM data stream for up-sampling the PCM data stream.

3. The method of claim 1 further comprising re-sampling the PCM data stream.

4. The method of claim 1, wherein generating the leading edge PWM signal comprises:
extracting an odd numbered PCM data stream from the PCM data stream; and
modulating the odd numbered PCM data stream to form the leading edge PWM signal.

5. The method of claim 1, wherein generating the leading edge PWM signal comprises:
extracting an even numbered PCM data stream from the PCM data stream; and
modulating the even numbered PCM data stream to form the leading edge PWM signal.

6. The method of claim 1, wherein generating the trailing edge PWM signal comprises:
extracting an odd numbered PCM data stream from the PCM data stream; and
modulating the odd numbered PCM data stream to form the trailing edge PWM signal.

7. The method of claim 1, wherein generating the trailing edge PWM signal comprises:
extracting an even numbered PCM data stream from the PCM data stream; and
modulating the even numbered PCM data stream to form the trailing edge PWM signal.

8. The method of claim 1, wherein a switching frequency of the leading edge PWM signal is equal to half of a sampling frequency of the PCM data stream.

9. The method of claim 1, wherein a switching frequency of the trailing edge PWM signal is equal to half of a sampling frequency of the PCM data stream.

10. A system for generating a double-sided Pulse Width Modulation (PWM) signal from a pulse code modulated (PCM) data stream, the system comprising:
a sampling block creating a first and a second PCM data stream by extracting an odd numbered PCM data stream and an even numbered PCM data stream from the PCM data stream;
at least one modulation conversion circuitry capable of generating a leading edge PWM signal and a trailing edge PWM signal from the first and the second PCM data stream; and
combining circuitry capable of combining the leading edge PWM signal and the trailing edge PWM signal to form the double-sided PWM signal.

11. The system of claim 10 further comprising an interpolator capable of interpolating the PCM data stream for up-sampling the PCM data stream to a sampling frequency suitable for PWM generation.

12. The system of claim 10 further comprising re-sampling circuitry capable of re-sampling the PCM data stream.

13. The system of claim 10, wherein the modulation conversion circuitry comprises a PCM data stream divider, the PCM data stream divider capable of generating an odd numbered PCM data stream and an even numbered PCM data stream.

14. The system of claim 13, wherein a sampling frequency of the odd numbered PCM data stream and a sampling frequency of the even numbered PCM data stream are equal to half of a sampling frequency of the PCM data stream.

15. The system of claim 13 further comprising a PCM memory capable of storing at least one of the odd numbered PCM data stream and the even numbered PCM data stream.

16. The system of claim 10 further comprising a PWM memory capable of storing at least one of the leading edge PWM signal and the trailing edge PWM signal.
